(19) United States
(12) Patent Application Publication
(10) Pub. No.: US 2023/0418399 A1
(43) Pub. Date: Dec. 28, 2023

(54) DISPLAY DEVICE AND MANUFACTURING METHOD OF THE SAME

(71) Applicant: Samsung Display Co., LTD., Yongin-si (KR)

(72) Inventors: HONGBEOM LEE, Yongin-si (KR); DAE-HYUN NOH, Yongin-si (KR); SOYUL JEON, Yongin-si (KR); JIN-HO JEONG, Yongin-si (KR); DONGWOOK KIM, Yongin-si (KR); JINHO KIM, Yongin-si (KR); HYEJIN KIM, Yongin-si (KR); HYUNGCHUL LIM, Yongin-si (KR)

(21) Appl. No.: 18/131,623

(22) Filed: Apr. 6, 2023

(30) Foreign Application Priority Data
Jun. 24, 2022 (KR) 10-2022-0077346

(51) Int. Cl. G06F 3/041; H10K 59/12; H10K 59/40

(52) U.S. Cl. CPC G06F 3/0412; G06F 3/04164; G06F 2203/04103; H10K 59/40; H10K 59/12

(57) ABSTRACT

Provided is a display device according to an embodiment including a display panel including a display region and a non-display region, and an input sensing unit disposed on the display panel, wherein the input sensing unit includes a first sensing insulating layer disposed on the display panel, and a first sensing conductive layer disposed on the first sensing insulating layer, and the first sensing insulating layer has an atomic ratio of nitrogen (N) to silicon (Si) of about 0.69 to about 0.85. Accordingly, corrosion of the electrode and wires due to the electric field when the input sensing unit is driven may be controlled. Accordingly, reliability of the display device may be improved.

This application claims priority to Korean Patent Application No. 10-2022-0077346, filed on Jun. 24, 2022, and all the benefits accruing therefrom under 35 U.S.C. § 119, the content of which in its entirety is herein incorporated by reference.

### BACKGROUND

The present disclosure herein relates to a display device and a manufacturing method of the same, and more particularly, to a display device having improved reliability by preventing corrosion of metal.

Electronic apparatuses, such as smart phones, digital cameras, laptop computers, navigation units, and televisions, which provide an image to a user, include a display device for displaying the image. The display device may include a display panel for generating and displaying an image and an input device such as a keyboard, a mouse, or an input sensing unit.

The input sensing unit is disposed on the display panel, and when a user touches an input sensing unit such as a touch panel, an input signal is generated. The input signal generated from the touch panel is provided to the display panel, and in response to the input signal provided from the touch panel, the display panel may provide the user with the image corresponding to the input signal.

### SUMMARY

The present disclosure provides a display device having improved reliability by preventing corrosion of electrodes and wires included in an input sensing unit.

An embodiment of the present invention provides a display device including: a display panel including a display region and a non-display region; and an input sensing unit disposed on the display panel, where the input sensing unit includes a first sensing insulating layer disposed on the display panel, and a first sensing conductive layer disposed on the first sensing insulating layer, and the first sensing insulating layer has an atomic ratio of nitrogen (N) to silicon (Si) of about 0.69 to about 0.85.

In an embodiment, the first sensing insulating layer may include at least one of silicon nitride or silicon oxynitride.

In an embodiment, the input sensing unit includes a non-bending region and a bending region extending from the non-bending region and having a predetermined radius of curvature, the first sensing insulating layer includes a bending sensing insulating layer disposed in the bending region, and a non-bending sensing insulating layer disposed in the non-bending region, and the bending sensing insulating layer has an atomic ratio of nitrogen (N) to silicon (Si) of about 0.69 to about 0.85.

In an embodiment, the display device may further include a bending protective layer disposed on the input sensing unit, where the bending protective layer overlaps the bending region and may cover a portion of the input sensing unit.

In an embodiment, the display panel may include a display element layer including a plurality of light-emitting elements and an encapsulation layer configured to encapsulate the display element layer, and the input sensing unit may be disposed directly on the encapsulation layer.

In an embodiment, the encapsulation layer may include a first inorganic layer disposed on the display element layer, an organic layer disposed on the first inorganic layer, and a second inorganic layer disposed on the organic layer, and the input sensing unit may be disposed directly on the second inorganic layer.

In an embodiment, the first sensing insulating layer may have a film density of about 2 grams per cubic centimeter (g/cm³) to about 2.2 g/cm³.

In an embodiment, the first sensing insulating layer may have a residual stress of about −250 megapascals (MPa) to about −100 MPa.

In an embodiment, the first sensing insulating layer may have a refractive index of about 1.75 to about 1.95.

In an embodiment, the input sensing unit may further include: a second sensing insulating layer disposed on the first sensing insulating layer and configured to cover the first sensing conductive layer; and a second sensing conductive layer disposed on the second sensing insulating layer.

In an embodiment, the second sensing insulating layer may include at least one of aluminum oxide, titanium oxide, silicon oxide, silicon nitride, silicon oxynitride, zirconium oxide, or hafnium oxide.

In an embodiment, the display device may further include a third sensing insulating layer disposed on the second sensing insulating layer and configured to cover the second sensing conductive layer, and the third sensing insulating layer may include an organic material.

In an embodiment, an electrode contact hole, which exposes at least a portion of the first sensing conductive layer and overlaps the display region, may be defined in the second sensing insulating layer, and the second sensing conductive layer may be electrically connected to the first sensing conductive layer through the electrode contact hole.

In an embodiment, the input sensing unit may include: a plurality of sensing patterns overlapping the display region and arranged in a plurality of rows and a plurality of columns; a plurality of sensing pads overlapping the non-display region; and a plurality of sensing wires connected to the plurality of sensing pads in a one-to-one manner such that the plurality of sensing wires electrically connects the plurality of sensing patterns and the plurality of sensing pads, where the plurality of sensing patterns is included in at least one of the first sensing conductive layer or the second sensing conductive layer.

In an embodiment, a pad contact hole exposing at least a portion of the plurality of sensing pads may be defined in the second sensing insulating layer, and the sensing wires may be electrically connected to the plurality of sensing pads through the pad contact hole.

In an embodiment of the present invention, a display device includes: a display panel including a display region; and an input sensing unit disposed on the display panel, where the input sensing unit includes a plurality of sensing insulating layers and at least one sensing conductive layer disposed on any one of the plurality of sensing insulating layers, and at least one of the plurality of sensing insulating layers has an atomic ratio of nitrogen (N) to silicon (Si) of about 0.69 to about 0.85.

In an embodiment of the present invention, a method of manufacturing a display device includes: forming a first sensing insulating layer on a display panel; forming a first sensing conductive layer on the first sensing insulating layer; forming a second sensing insulating layer disposed on the first sensing insulating layer and configured to cover the first sensing conductive layer; and forming a second sensing conductive layer disposed on the second sensing insulating layer, where the first sensing insulating layer has an atomic ratio of nitrogen (N) to silicon (Si) of about 0.69 to about 0.85.

In an embodiment, the forming of the first sensing insulating layer may be performed by a deposition process, and the forming of the first sensing insulating layer may be performed at a temperature of about 70° C. to about 100° C.

### BRIEF DESCRIPTION OF THE FIGURES

The accompanying drawings are included to provide a further understanding of the present invention, and are incorporated in and constitute a part of this specification. The drawings illustrate embodiments of the present invention and, together with the description, serve to explain principles of the present invention. In the drawings:

FIG. 1A is a combined perspective view of a display device according to an embodiment of the present invention;

FIG. 1B is an exploded perspective view of a display device according to an embodiment of the present invention;

FIG. 2A is a cross-sectional view of a display module according to an embodiment of the present invention;

FIG. 2B is a cross-sectional view illustrating a partial configuration of a display device according to an embodiment of the present invention;

FIG. 3A is a plan view of a display panel according to an embodiment of the present invention;

FIG. 3B is a cross-sectional view of a display panel according to an embodiment of the present invention;

FIG. 4 is a schematic cross-sectional view of a display module according to an embodiment of the present invention;

FIG. 5 is a plan view of an input sensing unit according to an embodiment of the present invention;

FIG. 6 is a cross-sectional view illustrating a partial configuration of an input sensing unit according to an embodiment of the present invention; and

FIG. 7 is a cross-sectional view of a portion of an input sensing unit according to an embodiment of the present invention.

### DETAILED DESCRIPTION

Hereinafter, embodiments of the present invention will be described with reference to the drawings.

In this specification, it will also be understood that when a component (a region, a layer, a portion, or the like) is referred to as “being on”, “being connected to”, or “being coupled to” another component, it may be directly connected/coupled to the another component, or an intervening third component may be also disposed therebetween. For example, “directly disposed” may mean disposing without additional members such as adhesive members between two layers or two members.

Like numbers or symbols refer to like elements throughout. Also, in the drawings, the thicknesses, ratios, and dimensions of the elements are exaggerated for effective description of the technical contents. The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” The term “and/or” includes all of one or more combinations which can be defined by related components.

Although the terms “first,” “second,” etc. may be used to describe various elements, these elements should not be limited by these terms. These terms are only used to distinguish one element from another element. For example, a first element may be referred to as a second element, and similarly, a second element may also be referred to as a first element without departing from the scope of the present disclosure. The singular forms include the plural forms as well, unless the context clearly indicates otherwise.

Also, terms such as “below”, “lower”, “above”, and “upper” may be used to describe the relationships of the components illustrated in the drawings. These terms have relative concepts and are described on the basis of the directions indicated in the drawings.

It will be understood that the term “includes” or “comprises”, when used in this specification, specifies the presence of stated features, integers, steps, operations, elements, components, or a combination thereof, but does not preclude the presence or addition of one or more other features, integers, steps, operations, elements, components, or combinations thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which the present disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

Hereinafter, a display device according to an embodiment of the present invention and a manufacturing method of the same will be described with reference to the drawings.

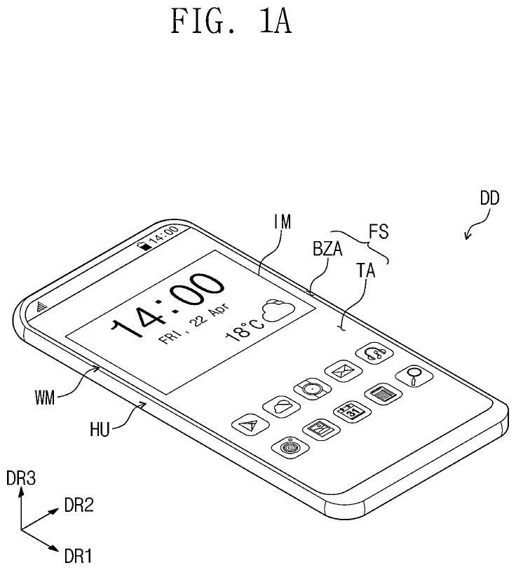

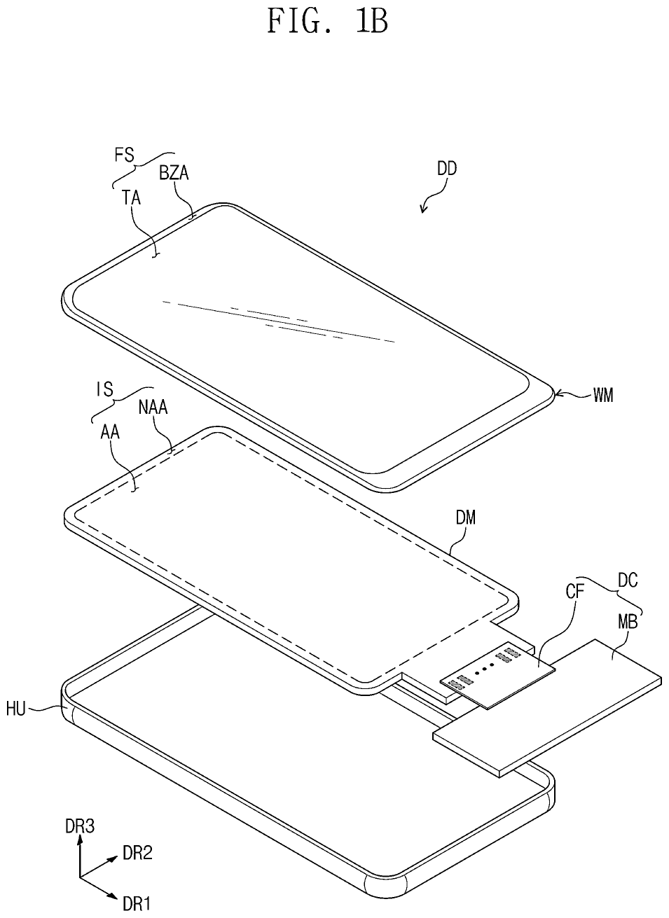

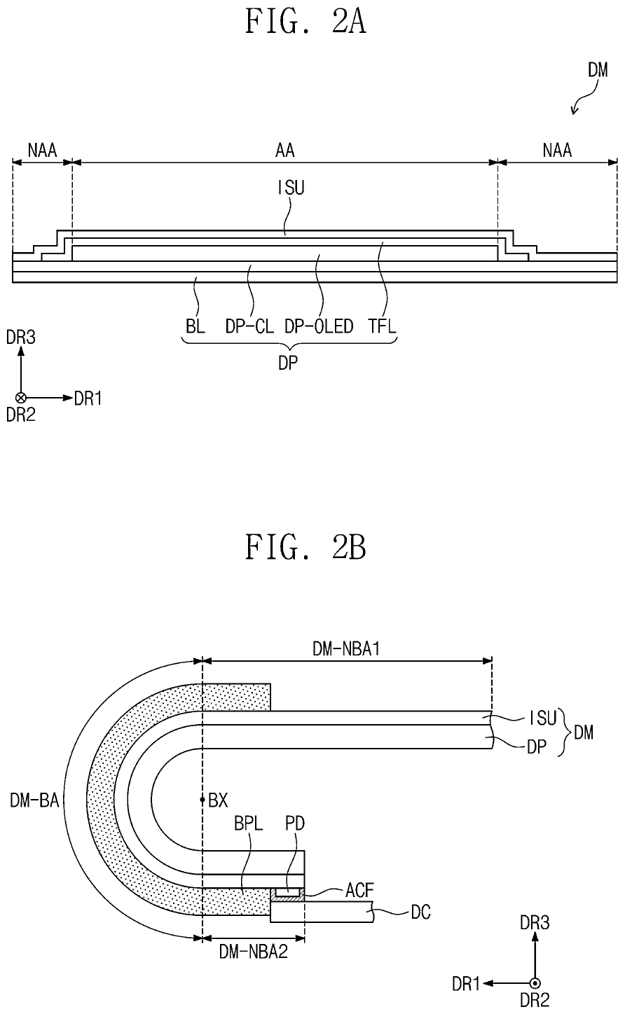

FIG. 1A is a combined perspective view of a display device according to an embodiment of the present invention. FIG. 1B is an exploded perspective view of a display device according to an embodiment of the present invention. FIG. 2A is a cross-sectional view of a display module according to an embodiment of the present invention. FIG. 2B is a cross-sectional view illustrating a partial configuration of a display device according to an embodiment of the present invention.

Referring to FIG. 1A, a display device DD may be a device activated in response to an electrical signal. The display device DD may display an image IM and sense an external input TC. The display device DD may include various embodiments. For example, the display device DD may include a tablet, a laptop computer, a computer, a smart television, or the like. In this embodiment, the display device DD is illustratively shown as a smart phone.

The display device DD may display an image IM, in a third direction DR3, on a display surface FS parallel to each of a first direction DR1 and a second direction DR2. The display surface FS, on which the image IM is displayed, may correspond to a front surface of the display device DD and may also correspond to a front surface FS of a window member WM. Hereinafter, the same reference symbol is used to denote the display surface and front surface of the display device DD and the front surface of the window member WM. The image IM may include static images as well as dynamic images. In FIG. 1A, a clock and a plurality of icons are illustrated as examples of the image IM.

In this embodiment, a front surface (or a front surface) and a rear surface (or a bottom surface) of each member are defined based on the direction in which the image IM is displayed. The front and rear surfaces may be opposed to each other in the third direction DR3, and the normal direction of each of the front and rear surfaces may be parallel to the third direction DR3. The distance between the front and rear surfaces in the third direction DR3 may correspond to the thickness of a display panel DP in the third direction DR3. Here, directions indicated by the first to third directions DR1, DR2, and DR3 may have a relative concept and may thus be changed to other directions. Hereinafter, the first to third directions are the directions indicated by the first to third directions DR1, DR2, and DR3, respectively, and are thus denoted as the same reference numerals or symbols. Also, in this specification, the wording “in a plan view” may indicate viewing in the third direction DR3.

The display device DD according to an embodiment of the present invention may sense a user's input applied from the outside. For example, the user's input includes various types of external inputs such as a portion of the user's body, light, heat, or pressure. The user's input may be provided in various forms. Also, the display device DD may also sense the user's input applied to a side surface or a rear surface of the display device DD according to a structure of the display device DD, but is not limited to any one embodiment.

As illustrated in FIGS. 1A and 1B, the display device DD includes a window member WM, a display module DM, a driving circuit DC, and an outer case HU. In this embodiment, the window member WM and the outer case HU are coupled to form an exterior of the display device DD. In this embodiment, the outer case HU, the display module DM, and the window member WM may be sequentially stacked along the third direction DR3.

The window member WM may include an optically transparent material. The window member WM may include an insulating panel. For example, the window member WM may be composed of glass, plastic, or a combination thereof.

As described above, the front surface FS of the window member WM defines the front surface of the display device DD. A transmission region TA may be an optically transparent region. For example, the transmission region TA may be a region having a visible light transmittance of about 90% or higher.

A bezel region BZA may be a region having a relatively lower light transmittance than the transmission region TA. The bezel region BZA defines the shape of the transmission region TA. The bezel region BZA may be adjacent to the transmission region TA and may surround the transmission region TA.

The bezel region BZA may have a predetermined color. The bezel region BZA may cover the peripheral region NAA of the display module DM to prevent the peripheral region NAA from being viewed from the outside. However, this is merely illustrated as an example. The bezel region BZA may be omitted in the window member WM according to an embodiment of the present invention.

The display module DM may display the image IM and sense an external input. The image IM may be displayed on the front surface IS of the display module DM. The front surface IS of the display module DM includes an active region AA (in other words, “display region”) and a peripheral region NAA (in other words, “non-display region”). The active region AA may be activated in response to an electrical signal.

In this embodiment, the active region AA may be a region in which the image IM is displayed and an external input TC is sensed. The transmission region TA overlaps at least the active region AA. For example, the transmission region TA overlaps the active region AA entirely or at least partially. Accordingly, a user may view the image IM and provide the external input through the transmission region TA. However, this is merely an example. In the active region AA, a region in which the image IM is displayed and a region in which the external input is sensed may be separated from each other, and the active region AA is not limited to one embodiment.

The peripheral region NAA may be a region covered by the bezel region BZA. The peripheral region NAA is adjacent to the active region AA. The peripheral region NAA may surround the active region AA. A driving circuit, a driving wire, or the like for driving the active region AA may be disposed in the peripheral region NAA. In the present specification, the active area AA may be defined as a “display region”, and the peripheral area NAA may be defined as a “non-display region”.

The display module DM may include a display panel and an input sensing unit. The image IM may be substantially displayed on the display panel, and an external input may be substantially sensed by the input sensing unit. Since the display module DM includes both the display panel and the input sensing unit, the display module DM may display an image IM and simultaneously sense an external input. This will be described in detail later. The driving circuit DC may include a flexible circuit board CF and a main circuit board MB. The flexible circuit board CF may be electrically connected to the display module DM. The flexible circuit board CF may connect the display module DM and the main circuit board MB. However, this is illustrated as an example, and the flexible circuit board CF according to an embodiment of the present invention may not be connected to the main circuit board MB, and the flexible circuit board CF may be a rigid board.

The flexible circuit board CF may be connected to pads of the display module DM disposed in the peripheral region NAA. The flexible circuit board CF may provide an electrical signal for driving the display module DM to the display module DM. The electrical signal may be generated from the flexible circuit board CF or generated from the main circuit board MB.

The main circuit board MB may include various driving circuits for driving the display module DM or connectors for supplying power. The main circuit board MB may be connected to the display module DM through the flexible circuit board CF.

Although FIG. 1B exemplarily illustrates an unfolded state of the display module DM, at least a portion of the display module DM may be bent. In this embodiment, a portion of the display module DM to which the main circuit board MB is connected is bent toward the rear surface of the display module DM, so that the main circuit board MB may be assembled while overlapping the rear surface of the display module DM.

The outer case HU is coupled to the window member WM to define the exterior of the display device DD. The outer case HU provides a predetermined inner space. The display module DM may be accommodated in the inner space.

The outer case HU may include a material having relatively high rigidity. For example, the outer case HU may include glass, plastic, or metal or may include a plurality of frames and/or plates having a combination of glass, plastic, and metal. The outer case HU may stably protect components of the display device DD, which are accommodated in the inner space, against external impacts.

Referring to FIG. 2A, the display module DM may include a display panel DP and an input sensing unit ISU. The display panel DP may be configured to substantially generate the image IM. The image IM (see FIGS. 1A and 1B) generated by the display panel DP may be viewed by the user from the outside through the transmission region TA (see FIGS. 1A and 1B).

The display panel DP may be a light-emitting-type display panel, and is not particularly limited. For example, the display panel DP may be an organic light-emitting display panel or an inorganic light-emitting display panel. The organic light-emitting display panel may be a display panel in which the light-emitting layer includes an organic light-emitting material. The inorganic light-emitting display panel may be a display panel in which the light-emitting layer includes quantum dots, quantum rods, or micro LEDs. Hereinafter, the display panel DP is described as the organic light-emitting display panel.

The input sensing unit ISU may be disposed on the display panel DP. The input sensing unit ISU may sense an external input applied from the outside. The external input may include various types of inputs provided from the outside of the display device DD (see FIG. 1A). An external input applied from the outside may be provided in various forms. For example, the external input may include not only a touch from a part of the user's body such as a hand but also an external input (for example, hovering) applied when approaching the display device DD or brought close thereto within a predetermined distance. Also, the external input may have various types such as force, pressure, and light, but is not limited to one embodiment.

The input sensing unit ISU may be formed on the display panel DP through a continuous process. In this case, the input sensing unit ISU may be disposed directly on the display panel DP. In this specification, the wording “component A is disposed directly on component B” may mean that a third component is not disposed between components A and B. For example, an adhesive layer may not be disposed between the input sensing unit ISU and the display panel DP.

The display panel DP may include a base layer BL, a circuit element layer DP-CL disposed on the base layer BL, a display element layer DP-OLED, and an upper insulating layer TFL.

The base layer BL may provide a base surface on which the circuit element layer DP-CL, the display element layer DP-OLED, and the upper insulating layer TFL are disposed. The base layer BL may be a rigid substrate or a flexible substrate capable of bending, folding, rolling, or the like. The base layer BL may be a glass substrate, a metal substrate, or a polymer substrate. However, an embodiment of the present invention is not limited thereto, and the base layer BL may include an inorganic layer, an organic layer, or a composite material layer.

The base layer BL may have a multi-layer structure. For example, the base layer BL may include a first synthetic resin layer, a multi- or single-layered inorganic layer, and a second synthetic resin layer disposed on the multi- or single-layered inorganic layer. Each of the first and second synthetic resin layers may include a polyimide-based resin, and is not particularly limited.

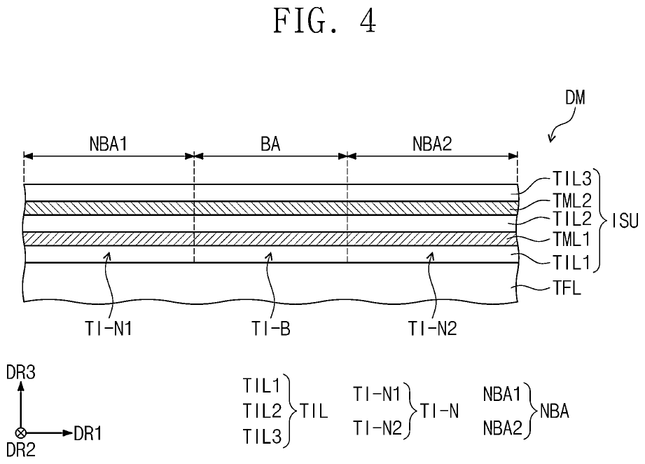

The circuit element layer DP-CL may be disposed on the base layer BL. The circuit element layer DP-CL may include a plurality of insulating layers, a plurality of conductive layers, and a semiconductor layer. A plurality of conductive layers of the circuit element layer DP-CL may constitute signal lines or a control circuit of a pixel PX (see FIG. 4).

The display element layer DP-OLED may be disposed on the circuit element layer DP-CL. The display element layer DP-OLED may include organic light-emitting elements. However, this is merely an example, and the display element layer DP-OLED according to an embodiment of the present invention may include inorganic light-emitting elements, organic-inorganic light-emitting elements, or a liquid crystal layer.

The upper insulating layer TFL may include a capping layer and a thin-film encapsulation layer which will be described later. The upper insulating layer TFL may include an organic layer and a plurality of inorganic layers that seal the organic layer.

The upper insulating layer TFL may be disposed on the display element layer DP-OLED to protect the display element layer DP-OLED from foreign substances such as moisture, oxygen, and dust particles. The upper insulating layer TFL may seal the display element layer DP-OLED to block moisture and oxygen from flowing into the display element layer DP-OLED. The upper insulating layer TFL may include at least one inorganic layer. The upper insulating layer TFL may include an organic layer and a plurality of inorganic layers that seal the organic layer. The upper insulating layer TFL may include a stack structure in which the inorganic layer/organic layer/inorganic layer are stacked in this order.

The input sensing unit ISU is disposed on the upper insulating layer TFL. The input sensing unit ISU may be formed on the upper insulating layer TFL through a continuous process. The input sensing unit ISU may be disposed directly on display panel DP. That is, a separate adhesive member may not be disposed between the input sensing unit ISU and the display panel DP. The input sensing unit ISU may be disposed to contact the inorganic layer disposed on top of the upper insulating layer TFL.

Although not illustrated separately, the display module DM according to an embodiment of the present invention may further include a protective member disposed on a lower surface of the display panel DP and an anti-reflection member disposed on an upper surface of the input sensing unit ISU. The anti-reflection member may reduce the reflectance of external light. The anti-reflection member may be disposed directly on the input sensing unit ISU through a continuous process.

The anti-reflection member may include a light blocking pattern overlapping a reflective structure disposed below the anti-reflection member in a plan view. The anti-reflection member may further include a color filter. The color filter may be disposed between the light blocking patterns, and may include a first color filter, a second color filter, and a third color filter corresponding to the first color pixel, the second color pixel, and the third color pixel, respectively.

Referring to FIG. 2B, a portion of the display module DM may be bent. The display module DM may include a first non-bending region DM-NBA1, a second non-bending region DM-NBA2 spaced apart from the first non-bending region DM-NBA1 in the first direction, and a bending region DM-BA defined between the first non-bending region DM-NBA1 and the second non-bending region DM-NBA2.

The bending region DM-BA may be bent along the virtual bending axis BX extending in the second direction DR2. Referring to FIG. 2B, as the bending region DM-BA may be bent, the second non-bending region DM-NBA2 may be disposed below the first non-bending region DM-NBA1 and may face the first non-bending region DM-NBA′.

A driving circuit DC may be connected to the display module DM. For example, the driving circuit DC may be connected to one side of the second non-bending region DM-NBA2 of the display module DM. Although not illustrated, the driving circuit DC may include a base layer and a timing controller disposed on the base layer. The timing controller may be formed as an integrated circuit chip and mounted on an upper surface of the base layer. The driving circuit DC may be electrically connected to the display module DM through a pad part PD included in the display module DM. The driving circuit DC may be electrically connected to the pad part PD through an anisotropic conductive film ACF. Although not illustrated, the driving circuit DC may include a circuit pad, and the circuit pad may be electrically connected to the pad part PD through the anisotropic conductive film ACF. The pad part PD may correspond to a sensing pad to be described later with reference to FIG. 7.

The bending region DM-BA may be bent such that the second non-bending region DM-NBA2 is disposed below the first non-bending region DM-NBA′. Accordingly, the driving circuit DC connected to the second non-bending region DM-NBA2 may be disposed below the first non-bending region DM-NBA′. That is, the first non-bending region DM-NBA1 and the second non-bending region DM-NBA2 may be disposed on different planes (or reference planes). The bending region DM-BA may be bent to be horizontally convex in cross-section. The bending region DM-BA has a predetermined curvature and a radius of curvature. The radius of curvature may be about 0.1 millimeters (mm) to about 0.5 mm.

The display device DD may include a bending protective layer BPL disposed on the display module DM. The bending protective layer BPL may be disposed on the bending region BA of the display module DM. The bending protective layer BPL may be disposed on the bending region BA of the input sensing unit ISU and may cover a portion of the input sensing unit ISU. The bending protective layer BPL may perform a function of alleviating stress generated according to the bending of the display panel DP.

The bending protective layer BPL may be bent together with the bending region BA. The bending protective layer BPL protects the bending region DM-BA from external impact and controls a neutral plane of the bending region DM-BA. The bending protective layer BPL controls the stress of the bending region DM-BA so that the neutral plane approaches the signal lines disposed in the bending region DM-BA.

The bending protective layer BPL may overlap at least the bending region DM-BA. The bending protective layer BPL may overlap at least a portion among the first non-bending region DM-NBA1, the bending region DM-BA, and the second non-bending region DM-NBA2 of the display module DM. In an embodiment, the bending protective layer BPL may overlap only a portion of each of the first non-bending region DM-NBA1 and the second non-bending region DM-NBA2. The bending protective layer BPL may not overlap the above-described active region AA (see FIG. 2A). FIG. 2B exemplarily illustrates that one side of the bending protective layer BPL contacts the driving circuit DC, but an embodiment of the present invention is not limited thereto. For example, one side of the bending protective layer BPL may be disposed to be spaced apart from the edge of the driving circuit DC in a plan view in another embodiment.

Although not illustrated, the bending protective layer BPL may overlap at least a portion of the driving circuit DC in a plan view. The bending protective layer BPL may be disposed on a portion of the first non-bending region DM-NBA1 adjacent to the bending region DM-BA, and may extend to the bending region DM-BA and the second non-bending region DM-NBA2 to cover the edge of the driving circuit DC coupled to the second non-bending region DM-NBA2 of the display module DM. The bending protective layer BPL may not overlap the driving circuit DC in a plan view.

The bending protective layer BPL may have a thickness of about 500 μm or less. For example, the bending protective layer BPL may have a thickness of about 10 μm to about 200 μm. When the thickness of the bending protective layer BPL satisfies the above range, durability and flexibility may be secured without excessively increasing the total thickness of the bending protective layer BPL, so that the display device DD with improved mechanical reliability may be achieved. In this specification, the thickness of the bending protective layer BPL may represent an average value of the thickness of the bending protective layer BPL provided on one surface of the display panel DP in the third direction DR3. The thickness of the bending protective layer BPL may be an arithmetic average of thickness values of the bending protective layer BPL measured as the shortest distance from the lower surface of the bending protective layer BPL to the upper surface of the bending protective layer BPL.

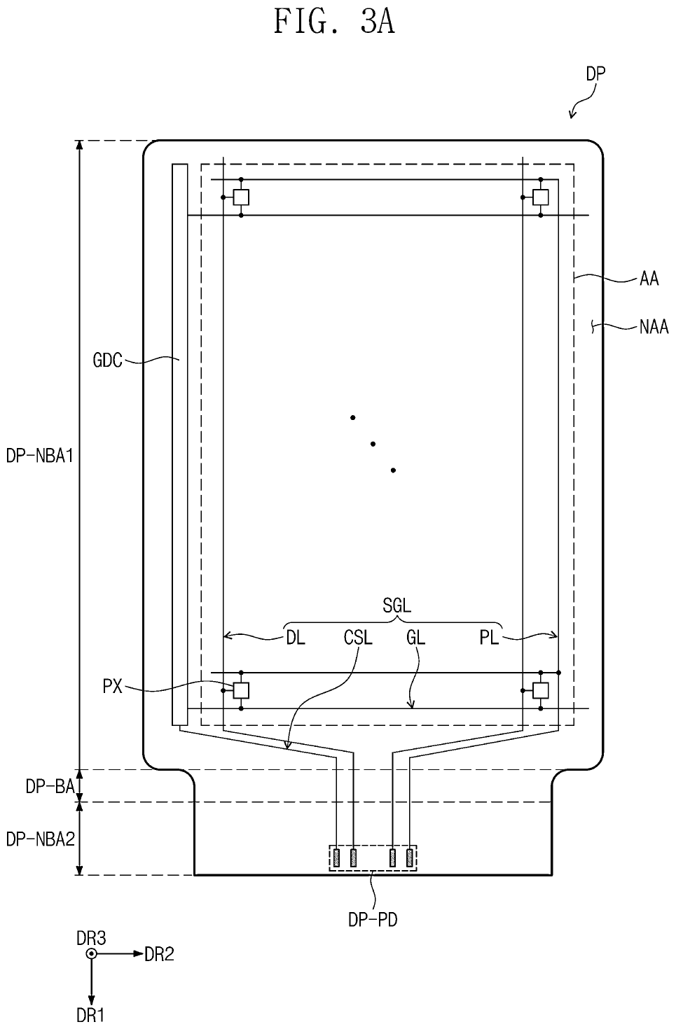

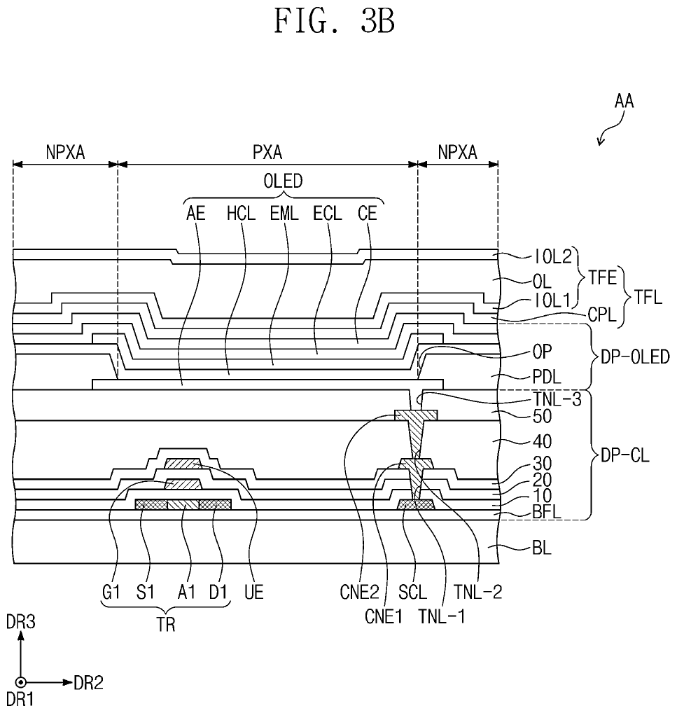

FIG. 3A is a plan view of a display panel according to an embodiment of the present invention. FIG. 3B is a cross-sectional view of a display panel according to an embodiment of the present invention.

Referring to FIG. 3A, the display panel DP may be divided into an active region AA and a peripheral region NAA. The active region AA of the display panel DP may be a region in which the image is displayed, and the peripheral region NAA may be a region in which a driving circuit or a driving wire is disposed. In the active region AA, the light-emitting elements of each of the plurality of pixels PX may be disposed. The active region AA may overlap at least a portion of the transmission region TA (see FIG. 1B) of the window member WM (see FIG. 1B), and the peripheral region NAA may be covered by the bezel region BZA (see FIG. 1B) of the window member WM (see FIG. 1B). The active region AA and the peripheral region NAA of the display panel DP may correspond to the active region AA and the peripheral region NAA of the display module DM illustrated in FIG. 1B, respectively.

According to an embodiment of the present invention, the display panel DP may include a plurality of pixels PX (hereinafter referred to as pixels), a plurality of signal lines SGL, a scan driving circuit GDC, and a display pad part DP-PD.

Each of the pixels PX may include a light-emitting element and a plurality of transistors connected thereto. The pixels PX may emit light in response to an applied electrical signal.

The signal lines SGL may include scan lines GL, data lines DL, a power line PL, and a control signal line CSL. The scan lines GL may be connected to a corresponding pixel PX among the pixels PX, respectively. The data lines DL may be connected to a corresponding pixel PX among the pixels PX, respectively. The power line PL may be connected to the pixels PX to provide a power voltage. The control signal line CSL may provide control signals to the scan driving circuit.

The scan driving circuit GDC may be disposed in the peripheral region NAA. The scan driving circuit GDC may generate scan signals and sequentially output the scan signals to the scan lines GL. The scan driving circuit GDC may further output another control signal to the driving circuit of the pixels PX.

The scan driving circuit GDC may include a plurality of thin-film transistors which are formed through the same process as that for the driving circuit of the pixels PX, such as a low temperature polycrystalline silicon (“LTPS”) process or a low temperature polycrystalline oxide (“LTPO”) process.

In the display panel DP according to an embodiment, a portion of the display panel DP may be bent. The display panel DP may include a first non-bending region DP-NBA1, a second non-bending region DP-NBA2 spaced apart from the first non-bending region DP-NBA1 in the first direction DR1, and a bending region DP-BA defined between the first non-bending region DP-NBA1 and the second non-bending region DP-NBA2. The first non-bending region DP-NBA1 may include an active region AA and a portion of the peripheral region NAA. The peripheral region NAA may include the bending region DP-BA and the second non-bending region DP-NBA2.

The bending region DP-BA may be bent along a virtual axis extending in the second direction DR2. When the bending region DP-BA is bent, the second non-bending region DP-NBA2 may face the first non-bending region DP-NBA1. According to an embodiment, the width of the display panel DP in the second direction DR2 in the bending region DP-BA may be smaller than the width of the display panel DP in the second direction DR2 in the first non-bending region DP-NBA′.

The display pad part DP-PD may be disposed adjacent to an end of the second non-bending region DP-NBA2. The signal lines SGL may extend from the first non-bending region DP-NBA1 to the second non-bending region DP-NBA2 via the bending region DP-BA and may be connected to the display pad part DP-PD. The flexible circuit board CF (see FIG. 1B) may be electrically connected to the display pad part DP-PD. As the flexible circuit board CF (see FIG. 1B) is attached to the display pad part DP-PD through an anisotropic conductive film, etc., the display panel DP and the flexible circuit board CF (see FIG. 1B) may be electrically connected to each other.

Referring to FIGS. 3A and 3B, in the display panel DP according to an embodiment, a circuit element layer DP-CL, a display element layer DP-OLED, and an upper insulating layer TFL may be sequentially disposed on the base layer BL. The configuration of the circuit element layer DP-CL, the display element layer DP-OLED, and the upper insulating layer TFL will be described in detail with reference to FIG. 3B.

The circuit element layer DP-CL includes at least one insulating layer and circuit elements. The circuit element includes a signal line, a driving circuit of a pixel, and the like. The circuit element layer DP-CL may be formed through a process of forming an insulating layer, a semiconductor layer, and a conductive layer using coating, deposition, or the like, and through a process of patterning the insulating layer, the semiconductor layer, and the conductive layer using a photolithography process.

A buffer layer BFL may include a plurality of stacked inorganic layers. A semiconductor pattern is disposed on the buffer layer BFL. The buffer layer BFL improves a bonding force between the base layer BL and the semiconductor pattern.

The semiconductor pattern may include polysilicon. However, an embodiment of the present invention is not limited thereto, and the semiconductor pattern may include amorphous silicon or a metal oxide. FIG. 3B is only a partial diagram of a semiconductor pattern, and a semiconductor pattern may be further disposed in another region of the pixel PX in a plan view. The semiconductor pattern may be arranged in a specific rule across the pixels PX.

The semiconductor pattern exhibits different electrical characteristics depending on whether the semiconductor pattern is doped or not. The semiconductor pattern may include a first region A1 having low doping concentration and conductivity and second regions S1 and D1 having relatively high doping concentration and conductivity. One second region S1 may be disposed on one side of the first region A1, and the other second region D1 may be disposed on the other side of the first region A1. The second region S1 and D1 may be doped with an N-type dopant or a P-type dopant. A P-type transistor may include a doped region which is doped with the P-type dopant. The first region A1 may be an undoped region or may be doped with a lower concentration than those of the second regions S1 and D1.

The second regions S1 and D1 substantially serve as electrodes or signal lines. One second region S1 may correspond to a source of the transistor, and the other second region D1 may be a drain. FIG. 3B illustrates a portion of the connection signal line SCL formed from the semiconductor pattern. Although not illustrated separately, the connection signal line SCL may be connected to the drain of the transistor TR in a plan view.

A first insulating layer 10 may be disposed on the buffer layer BFL. The first insulating layer 10 overlaps all the plurality of pixels PX (see FIG. 3A) and covers the semiconductor pattern in a plan view. The first insulating layer 10 may be an inorganic layer and/or an organic layer and may have a single- or multi-layered structure. The first insulating layer 10 may include at least one of an aluminum oxide, a titanium oxide, a silicon oxide, a silicon oxynitride, a zirconium oxide, or a hafnium oxide. Not only the first insulating layer but also an insulating layer of the circuit element layer DP-CL to be described later may be an inorganic layer and/or an organic layer, and may have a single- or multi-layered structure.

A gate G1 is disposed on the first insulating layer 10. The gate G1 may be a portion of the metal pattern. The gate G1 overlaps the first region A1 in a plan view. In the process of doping the semiconductor pattern, the gate G1 may function as a mask.

A second insulating layer 20 may be disposed on the first insulating layer 10 and may cover the gate G1. The second insulating layer 20 overlaps the pixels PX (see FIG. 3A) in common in a plan view. An upper electrode UE may be disposed on the second insulating layer 20. The upper electrode UE may overlap the gate G1 in a plan view. The upper electrode UE may include a multi-layered metal layer. In an embodiment of the present invention, the upper electrode UE may be omitted.

The third insulating layer 30 may be disposed on the second insulating layer 20 and may cover the upper electrode UE. A first connection electrode CNE1 may be disposed on the third insulating layer 30. The first connection electrode CNE1 may be connected to the connection signal line SCL through a contact hole TNL-1 that passes through the first to third insulating layers 10 to 30.

A fourth insulating layer 40 may be disposed on the third insulating layer 30. The fourth insulating layer 40 may be an organic layer. The second connection electrode CNE2 may be disposed on the fourth insulating layer 40. The second connection electrode CNE2 may be connected to the first connection electrode CNE1 through a contact hole TNL-2 that passes through the fourth insulating layer 40. A fifth insulating layer 50 may be disposed on the fourth insulating layer 40 and may cover the second connection electrode CNE2. The fifth insulating layer 50 may be an organic layer. Although not illustrated, at least one layer of the fourth insulating layer 40 or the fifth insulating layer 50 may be omitted in another embodiment.

An organic light-emitting diode OLED may be disposed on the fifth insulating layer 50. The first electrode AE may be disposed on the fifth insulating layer 50. The first electrode AE is connected to the second connection electrode CNE2 through a contact hole TNL-3 that passes through the fifth insulating layer 50. An opening OP is defined in the pixel defining film PDL, and the pixel defining film PDL exposes at least a portion of the first electrode AE. The pixel defining film PDL may be an organic layer.

As illustrated in FIG. 3B, the active region AA may include a light-emitting region PXA and a non-light-emitting region NPXA adjacent to the light-emitting region PXA. A non-light-emitting region NPXA may surround the light-emitting region PXA. In this embodiment, the light-emitting region PXA is defined corresponding to a partial region of the first electrode AE exposed by the opening OP.

A hole control layer HCL may be disposed in common in the light-emitting region PXA and the non-light-emitting region NPXA. The hole control layer HCL may include a hole transport layer and may further include a hole injection layer. A light-emitting layer EML is disposed on the hole control layer HCL. The light-emitting layer EML may be disposed in a region corresponding to the opening OP. That is, the light-emitting layer EML may be formed separately in each of the pixels PX (see FIG. 3A).

An electron control layer ECL may be disposed on the light-emitting layer EML. The electron control layer ECL may include an electron transport layer and may further include an electron injection layer. The hole control layer HCL and the electron control layer ECL may be formed in common in the plurality of pixels by using an open mask.

The second electrode CE may be disposed on the electron control layer ECL. The second electrode CE may have an integrated shape and may be disposed in common in the plurality of pixels PX (see FIG. 3A).

The upper insulating layer TFL may be disposed on the display element layer DP-OLED and may include a plurality of thin films. According to an embodiment of the present invention, the upper insulating layer TFL may include a capping layer CPL and an encapsulation layer TFE disposed on the capping layer CPL. The capping layer CPL may be disposed on the second electrode CE and may contact the second electrode CE. The capping layer CPL may include an organic material.

The encapsulation layer TFE may include a first inorganic layer IOL1, an organic layer OL disposed on the first inorganic layer IOL1, and a second inorganic layer IOL2 disposed on the organic layer OL. The first inorganic layer IOL1 and the second inorganic layer IOL2 protect a display element layer DP-OLED against moisture/oxygen, and the organic layer OL protects the display element layer DP-OLED against impurities such as dust particles.

FIG. 4 is a schematic cross-sectional view of a display module according to an embodiment of the present invention.

Referring to FIG. 4, the input sensing unit ISU may be disposed on the upper insulating layer TFL. The input sensing unit ISU may be disposed directly on the encapsulation layer TFE (see FIG. 3B). The input sensing unit ISU may include a first sensing insulating layer TILL a second sensing insulating layer TIL2, a third sensing insulating layer TIL3, a first sensing conductive layer TML1 and a second sensing conductive layer TML2.

The first sensing insulating layer TIL1 may be disposed directly on the upper insulating layer TFL. The first sensing insulating layer TIL1 may be disposed directly on the encapsulation layer TFE (see FIG. 3B). The first sensing insulating layer TIL1 may be disposed directly on the second inorganic layer IOL2 (see FIG. 3B) of the encapsulation layer TFE (see FIG. 3B). The first sensing conductive layer TML1, the second sensing insulating layer TIL2, the second sensing conductive layer TML2, and the third sensing insulating layer TIL3 may be sequentially disposed on the first sensing insulating layer TILL

A partial region of the input sensing unit ISU may be bent. The input sensing unit ISU may include a non-bending region NBA and a bending region BA extending from the non-bending region NBA and having a predetermined radius of curvature. The non-bending region NBA may include a first non-bending region NBA1 and a second non-bending region NBA2 spaced apart from the first non-bending region NBA1 in the first direction DR1. The bending region BA may be disposed between the first bending region NBA1 and the second non-bending region NBA2. The first non-bending region NBA1, the bending region BA, and the second non-bending region NBA2 in the input sensing unit ISU may correspond to the first non-bending region DP-NBA1, the bending region DP-BA, and the second non-bending region DP-NBA2 in the display panel DP, respectively (see FIG. 3A).

Each of the first sensing conductive layer TML1 and the second sensing conductive layer TML2 may have a single- or multi-layered structure. The conductive layer having the multi-layered structure may include at least two or more layers of transparent conductive layers and metal layers. The conductive layer having the multi-layered structure may include metal layers having different metals.

Each of the first sensing conductive layer TML1 and the second sensing conductive layer TML2 may be a transparent conductive layer which includes at least one of indium tin oxide (“ITO”), indium zinc oxide (“IZO”), zinc oxide (ZnO), indium tin zinc oxide (“ITZO”), Poly(3,4-ethylenedioxythiophene) (“PEDOT”), metallic nanowires, or graphene. Each of the first sensing conductive layer TML1 and the second sensing conductive layer TML2 may be metal layers which include molybdenum, silver, titanium, copper, aluminum, or an alloy thereof.

For example, each of the first sensing conductive layer TML1 and the second sensing conductive layer TML2 may have a three-layer structure including titanium/aluminum/titanium. A metal having relatively high durability and low reflectivity may be applied to the outer layer of the conductive layer, and a metal having high electrical conductivity may be applied to the inner layer of the conductive layer.

The plurality of sensing insulating layers TIL may include a first sensing insulating layer TM1, a second sensing insulating layer TIL2, and a third sensing insulating layer TIL3.

In an embodiment, each of a first sensing insulating layer TIL1 and a second sensing insulating layer TIL2 may include an inorganic film. The inorganic film may include at least one of an aluminum oxide, a titanium oxide, a silicon oxide, a silicon nitride, a silicon oxynitride, a zirconium oxide, or a hafnium oxide. In an embodiment, the first sensing insulating layer TIL1 may include a silicon nitride. The first sensing insulating layer TIL1 may be composed of silicon nitride. The third sensing insulating layer TIL3 may include an organic film. The organic film may include at least one of an acrylic resin, a methacrylic resin, polyisoprene, a vinyl-based resin, an epoxy-based resin, a urethane-based resin, a cellulose-based resin, a siloxane-based resin, a polyimide-based resin, a polyamide-based resin, or a perylene-based resin. Alternatively, the organic film may include polyester.

The first sensing insulating layer TIL1 may be disposed to overlap the bending region BA of the input sensing unit ISU in a plan view. The first sensing insulating layer TIL1 may include a bending sensing insulating layer TI-B disposed in the bending region BA and a non-bending sensing insulating layer TI-N disposed in non-bending region NBA. The non-bending sensing insulating layer TI-N may include a first non-bending sensing insulating layer TI-N1 disposed in the first non-bending region NBA1 and a second non-bending sensing insulating layer TI-N2 disposed in the second non-bending region NBA2.

The first sensing insulating layer TIL1 includes at least silicon and nitrogen. The first sensing insulating layer has an atomic ratio of nitrogen (N) to silicon (Si) of about 0.69 to about 0.85. The bending sensing insulating layer TI-B disposed in the bending region BA of the first sensing insulating layer TIL1 may have an atomic ratio of nitrogen (N) to silicon (Si) of about 0.69 to about 0.85. The second sensing insulating layer TIL2 or the third sensing insulating layer TIL3 may also have an atomic ratio of nitrogen (N) to silicon (Si) of about 0.69 to about 0.85. As the atomic ratio of nitrogen (N) to silicon (Si) in the insulating layer has a specific value, the oxidation reaction of the insulating layer may be reduced, thereby preventing corrosion of the wires and electrodes in the conductive layer, and reducing deterioration at high temperature and high humidity. The atomic ratio of nitrogen (N) to silicon (Si) of the first sensing insulating layer TILL may be measured by X-ray photoelectron spectroscopy (“XPS”).

The first sensing insulating layer TIL1 may have a film density of about 2 g/cm³ to about 2.2 g/cm³. The bending sensing insulating layer TI-B may have a film density of about 2 g/cm³ to about 2.2 g/cm³. Accordingly, the film density of the first sensing insulating layer TIL1 may be higher than the film density of the second sensing insulating layer TIL2. As the film density of the first sensing insulating layer TIL1 has a specific value, an oxidation reaction of the first sensing insulating layer TIL1 may be reduced.

The residual stress of the first sensing insulating layer TIL1 may be about −250 megapascals (MPa) to about −100 MPa. The first sensing insulating layer TILL may have a refractive index of about 1.75 to about 1.95. As the residual stress of the first sensing insulating layer TIL1 has the above specific value, corrosion of wires and electrodes in the conductive layer may be prevented. Since the refractive index has the above specific numerical value, deterioration of optical properties of the display device according to an embodiment of the present invention may be prevented and optical efficiency may be improved.

A display device manufacturing method according to an embodiment of the present invention may include forming a first sensing insulating layer TIL1 on a display panel DP, forming a first sensing conductive layer TML1 on the first sensing insulating layer TILL forming a second sensing insulating layer TIL2 which is disposed on the first sensing insulating layer TIL1 and covers the first sensing conductive layer TML1, and forming a second sensing conductive layer TML2 disposed on the second sensing insulating layer TIL2. After the forming of the first sensing insulating layer TILL the first sensing insulating layer TIL1 may have an atomic ratio of nitrogen (N) to silicon (Si) of about 0.69 to about 0.85. The partial pressures and flow rates of a silicon-containing gas and a nitrogen-containing gas may be adjusted so that the first sensing insulating layer TIL1 manufactured in the forming of the first sensing insulating layer TIL1 has an atomic ratio of nitrogen to silicon of about 0.69 to about 0.85.

The forming of the first sensing insulating layer may be performed through a deposition process. Specifically, the forming of the first sensing insulating layer may be performed by a chemical vapor deposition (“CVD”) method. In an embodiment of the present invention, the forming of the first sensing insulating layer may be a single operation. Alternatively, the forming of the first sensing insulating layer may include a plurality of steps, such as a deposition process for each section, if necessary. The forming of the first sensing insulating layer may be performed at a temperature of about 70° C. to about 100° C. According to a deposition method at a specific temperature, the first sensing insulating layer TIL1 in which an oxidation reaction is reduced may be formed.

In the typical display device, the electrode or wire in the bending region in the input sensing unit is corroded. Specifically, as a portion, of a specific insulating layer in the input sensing unit, overlapping the bending region was oxidized, an ammonia gas, etc., was generated as a by-product. As a result, metals included in the electrode or wire were basified. Accordingly, when the input sensing unit was driven, galvanic corrosion due to an electric field occurred.

In a display device according to an embodiment of the present invention, since the atomic ratio of nitrogen (N) to silicon (Si) of the insulating layer in the input sensing unit is limited to a specific value, oxidation of an insulating layer is prevented, thereby making it possible to achieve a display device that is favorable to prevent corrosion of wires. In a display device according to an embodiment of the present invention, the film density of the inorganic film insulating layer may be increased due to a specific atomic composition ratio of silicon (Si) and nitrogen (N), and accordingly, thus creating an environment in which the oxidation reactivity of the inorganic film insulating layer is lowered. That is, as the film density of the inorganic film insulating layer increases, it is possible to prevent promotion of the oxidation reaction which occurs when the inorganic layer comes into contact with water or oxygen. Accordingly, since the oxidation reactivity of the insulating layer is lowered, a generation degree of a by-product gas may be lowered, and thus galvanic corrosion of the electrode or wire due to the electric field during driving may be prevented. In a display device according to an embodiment of the present invention, as described above, by limiting the atomic ratio of nitrogen to silicon in the insulating layer in the input sensing unit to a specific value, deterioration of the insulating layer and wires at high temperature and high humidity may be effectively prevented and also the adhesion to other layers may be maintained. In addition, in a display device according to an embodiment of the present invention, as described above, by limiting the film density and residual stress of the insulating layer to specific values, it is possible to achieve the effects of preventing metal corrosion of wires, etc., due to the electric field during driving of the display device, preventing deterioration in high temperature and high humidity, and maintaining interlayer adhesion. That is, in the input sensing unit and the display device including the same according to an embodiment of the present invention, an insulating layer in which the atomic ratio of silicon and nitrogen may be specified within a specific numerical range is arranged in the input sensing unit, so that metal corrosion of wires and electrodes in the input sensing unit may be prevented and the quality of the display device may be effectively improved.

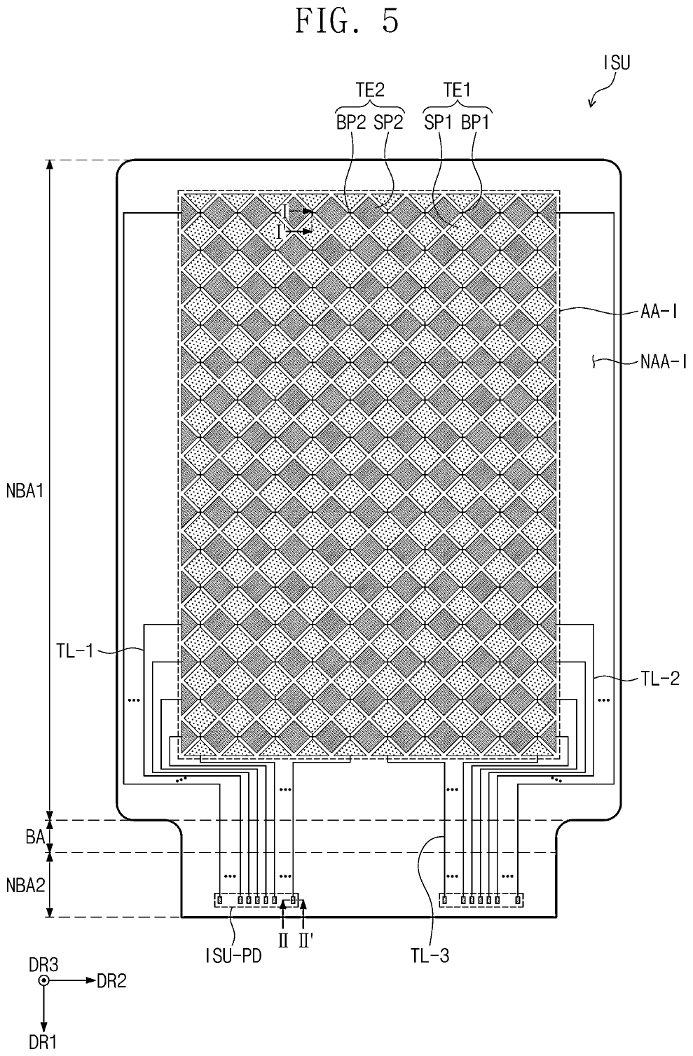

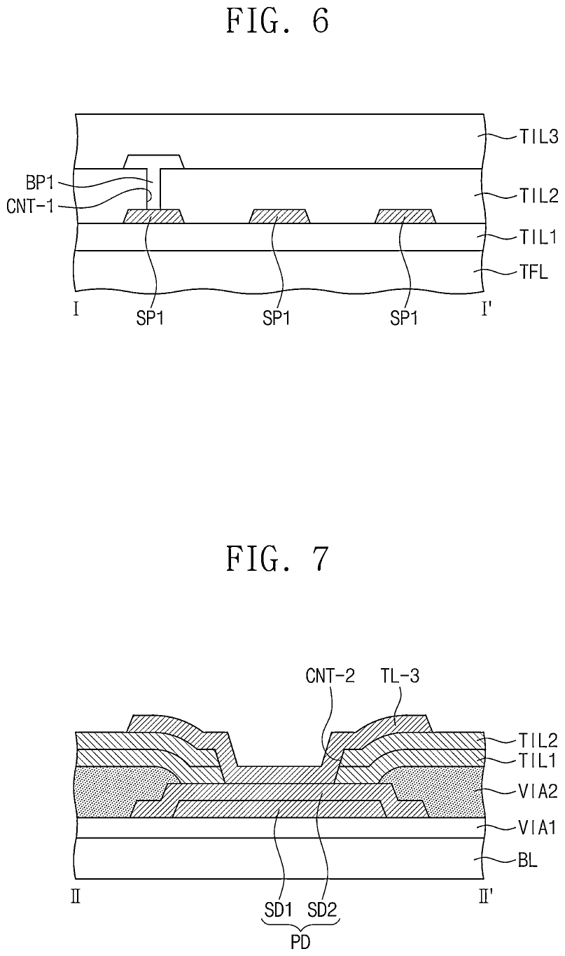

FIG. 5 is a plan view of an input sensing unit according to an embodiment of the present invention. FIGS. 6 and 7 are cross-sectional views each illustrating a partial configuration of an input sensing unit according to an embodiment of the present invention. FIG. 6 illustrates a cross-section taken along line I-I′ illustrated in FIG. 5. FIG. 7 illustrates a cross-section taken along line II-IP illustrated in FIG. 5.

Referring to FIG. 5, the input sensing unit ISU may be divided into an active region AA-I and a peripheral region NAA-I adjacent to the active region AA-I. The active region AA-I and the peripheral region NAA-I of the input sensing unit ISU may correspond to the active region AA (see FIG. 3A) and the peripheral region NAA (see FIG. 3A) of the display panel DP (see FIG. 3A), respectively. As described above in FIG. 4, the input sensing unit ISU may include the first non-bending region NBA1, the bending region BA, and the second non-bending region NBA2.

According to an embodiment of the present invention, the input sensing unit ISU may include a plurality of sensing electrodes TE1 and TE2, a plurality of sensing wires TL-1, TL-2, and TL-3 electrically connected to the sensing electrodes TE1 and TE2, and an input pad unit ISU-PD including a plurality of sensing pads. One-side ends of the plurality of sensing wires TL-1, TL-2, and TL-3 may be connected to the plurality of sensing electrodes TE1 and TE2, and the other-side ends of the sensing wires may be connected to the plurality of sensing pads disposed on the input pad unit ISU-PD.

The plurality of sensing electrodes TE1 and TE2 may include the first sensing electrodes TE1 and the second sensing electrodes TE2.

The first sensing electrodes TE1 may extend in the first direction DR1, may be provided in a plurality of columns, and may be arranged along the second direction DR2. The first sensing electrodes TE1 may include first sensing patterns SP1 and first conductive patterns BP1. The first sensing patterns SP1 may be arranged along the first direction DR1. At least one of the first conductive patterns BP1 may be connected to two adjacent first sensing patterns SP1. At least one first conductive pattern BP1 may be disposed between two adjacent first sensing patterns SP1.

The second sensing electrodes TE2 may extend in the second direction DR2, may be provided in a plurality of rows, and may be arranged along the first direction DR1. The second sensing electrodes TE2 may include second sensing patterns SP2 and second conductive patterns BP2. The second sensing patterns SP2 may be arranged along the second direction DR2. According to an embodiment of the present invention, the second sensing patterns SP2 and the second conductive patterns BP2 may have an integrally shaped pattern obtained through patterning by the same process.

Although not specifically illustrated, each of the first sensing electrodes TE1 and the second sensing electrodes TE2 may include a plurality of conductive lines crossing each other, and may have a mesh shape in which a plurality of openings are defined. Hereinafter, each of the first sensing electrodes TE1 and the second sensing electrodes TE2 having a mesh shape will be described as an example.

The first sensing patterns SP1, the second sensing patterns SP2, and the second conductive patterns BP2 illustrated in FIG. 5 may be included in the first sensing conductive layer TML1 described with reference to FIG. 4, and the first conductive patterns BP1 illustrated in FIG. 5 may be included in the second sensing conductive layer TML2 illustrated in FIG. 4.

The plurality of sensing wires TL-1, TL-2, and TL-3 may include the first sensing wire TL-1, the second sensing wire TL-2, and the third sensing wire TL-3. According to an embodiment of the present invention, the first sensing wires TL-1 may be connected to one-side ends of the rows of the second sensing electrodes TE2, respectively, and the second sensing wires TL-2 may be connected to the other-side ends of the rows of the second sensing electrodes TE2, respectively. The third sensing wires TL-3 may be connected to one-side ends of the columns of the first sensing electrodes TE1 adjacent to the bending region BA, respectively. However, an embodiment of the present invention is not limited thereto, and the sensing wires may be connected to only one-side ends or the other-side ends of the rows of the second sensing electrodes TE2 in another embodiment. That is, either of the first sensing wire TL-1 or the second sensing wire TL-2 may be omitted. In addition, the sensing wires may be additionally connected to the other-side ends opposite to one-side ends of the columns of the first sensing electrodes TE1 to which the third sensing wire TL-3 are connected in another embodiment.

As illustrated in FIGS. 5 and 6, the first sensing patterns SP1 included in the first sensing electrode TE1 may be disposed on the first sensing insulating layer TIL1. That is, the first sensing patterns SP1 may be included in the first sensing conductive layer TML1 described with reference to FIG. 4. The first conductive patterns BP1 included in the first sensing electrode TE1 may be disposed on the second sensing insulating layer TIL2. That is, the first conductive patterns BP1 may be included in the second sensing conductive layer TML2 described with reference to FIG. 4. The first conductive patterns BP1 may be electrically connected to the first sensing patterns SP1 through an electrode contact hole CNT-1 defined in the second sensing insulating layer TIL2. The first conductive patterns BP1 may be referred to as a “connection pattern”.

Although not illustrated, an anti-reflection member may be disposed directly on the input sensing unit. In an embodiment, the anti-reflection member may include a plurality of color filters and a light blocking pattern disposed between the color filters. The anti-reflection member may further include an overcoat layer that covers the color filter and the light blocking pattern.

Referring to FIGS. 5 and 7, the third sensing wire TL-3 may be connected to a sensing pad PD through the pad contact hole CNT-2 formed in the first sensing insulating layer TIL1 and the second sensing insulating layer TIL2. The sensing pad PD may include a plurality of conductive layers SD1 and SD2 and may be connected to a gate wire. The sensing pad PD may be disposed on the above-described input pad unit ISU-PD. The sensing pad PD may be disposed on the base layer BL, may be disposed on at least a portion of insulating layers VIA1 and VIA2, and may be covered by at least a portion of the insulating layers VIA1 and VIA2. Each of the insulating layers VIA1 and VIA2 may correspond to at least one of a plurality of insulating layers included in the circuit element layer DP-CL described with reference to FIG. 3B. FIG. 7 exemplarily illustrates that at least a portion of the third sensing wire TL-3 is disposed on the second sensing insulating layer TIL2. That is, FIG. 7 exemplarily illustrates that the third sensing wire TL-3 is included in the second sensing conductive layer TML2 described with reference to FIG. 4. However, an embodiment of the present invention is not limited thereto, and the third sensing wire TL-3 may be included in the first sensing conductive layer TML1 described with reference to FIG. 4. Alternatively, the third sensing wire TL-3 may be a double-layer wire that have a wire included in the first sensing conductive layer TML1 and a wire included in the second sensing conductive layer TML2.

Hereinafter, a display device according to an embodiment of the present invention will be described in detail with reference to the characteristic evaluation results of Examples and Comparative Examples. In addition, the following Examples are provided merely as examples to assist in the understanding of the present invention, and the scope of the present invention is not limited thereto.

### Preparation of Examples and Comparative Examples

Example (a) and Comparative Example (b) correspond to silicon nitride insulating layers prepared to have the physical properties shown in Table 1 below. Example (a) and Comparative Example (b) were prepared by a deposition process.

The composition ratio of nitrogen (N) to silicon (Si) in Table 1 was measured by X-ray photoelectron spectroscopy (XPS), the film density was measured by X-ray reflectometry (“XRR”), the residual stress was measured by a stress curvature measuring device, and the refractive index was measured by an ellipsometer.

TABLE 1

| | composition | film density | residual | refractive |
|---|---|---|---|---|
| | ratio (N/Si) | (g/cm²) | stress (MPa) | index |
| Example (a) | 0.79 | 2.15 | −207 | 1.841 |
| Comparative | 0.68 | 1.90 | −164 | 1.900 |
| Example (b) | | | | |

### Comparison of Characteristics of Examples and Comparative Examples

In order to analyze the oxidation reactivity of Examples (a) and Comparative Examples (b) prepared as above, oxygen (O) content of each insulating layer was measured through a transmission electron microscope (TEM). Table 2 below corresponds to the results showing the thicknesses of oxygen layers of Example (a) and Comparative Example (b) measured by TEM.

TABLE 2

| | Oxygen layer thickness in insulating layer (Å) |
|---|---|
| Example (a) | 350 |
| Comparative Example (b) | 2300 |

Referring to the results of Table 2, it may be seen that the thickness of the oxygen layer of Example (a) is significantly smaller than the thickness of the oxygen layer of Comparative Example (b). Considering that an oxide such as silicon oxide is generated when silicon nitride comes into contact with water or oxygen and thus an oxidation reaction occurs, it may be seen that the oxidation reactivity of the silicon nitride insulating layer is low when the thickness of the oxygen layer is small. Accordingly, according to the results of Table 2, it may be seen that an insulating layer of Example (a) had a significantly lower oxidation reactivity than an insulating layer of Comparative Example (b). In the display device according to an embodiment of the present invention, an input sensing unit may be obtained by including an insulating layer having a low oxidation reactivity since the insulating layer satisfies the above-described composition ratio range of nitrogen (N) to silicon (Si). In the input sensing unit according to an embodiment of the present invention, it is possible to prevent the corrosion of metals such as wires and electrodes in the input sensing unit due to an electric field during driving by reducing gas generation of by-products through the implementation of an insulating layer with a low oxidation reactivity.

According to a display device according to an embodiment of the present invention, corrosion of electrodes and wires due to an electric field during driving may be controlled without deterioration at high temperature and high humidity. Accordingly, the reliability of the display device may be improved.

Although the embodiments of the present invention have been described, it is understood that the present invention should not be limited to these embodiments but various changes and modifications can be made by one ordinary skilled in the art within the spirit and scope of the present invention as hereinafter claimed.

What is claimed is:

1. A display device comprising:
a display panel including a display region and a non-display region; and
an input sensing unit disposed on the display panel,
wherein the input sensing unit includes a first sensing insulating layer disposed on the display panel, and a first sensing conductive layer disposed on the first sensing insulating layer, and
the first sensing insulating layer has an atomic ratio of nitrogen (N) to silicon (Si) of about 0.69 to about 0.85.

2. The display device of claim 1, wherein the first sensing insulating layer comprises at least one of silicon nitride or silicon oxynitride.

3. The display device of claim 1, wherein
the input sensing unit comprises a non-bending region and a bending region extending from the non-bending region and having a predetermined radius of curvature,
the first sensing insulating layer includes a bending sensing insulating layer disposed in the bending region, and a non-bending sensing insulating layer disposed in the non-bending region, and
the bending sensing insulating layer has an atomic ratio of nitrogen (N) to silicon (Si) of about 0.69 to about 0.85.

4. The display device of claim 3, further comprising a bending protective layer disposed on the input sensing unit,
wherein the bending protective layer overlaps the bending region and covers a portion of the input sensing unit.

5. The display device of claim 1, wherein the display panel comprises a display element layer including a plurality of light-emitting elements and an encapsulation layer configured to encapsulate the display element layer, and
the input sensing unit is disposed directly on the encapsulation layer.

6. The display device of claim 5, wherein the encapsulation layer comprises a first inorganic layer disposed on the display element layer, an organic layer disposed on the first inorganic layer, and a second inorganic layer disposed on the organic layer, and
the input sensing unit is disposed directly on the second inorganic layer.

7. The display device of claim 1, wherein the first sensing insulating layer has a film density of about 2 grams per cubic centimeter (g/cm³) to about 2.2 g/cm³.

8. The display device of claim 1, wherein the first sensing insulating layer has a residual stress of about −250 megapascals (MPa) to about −100 MPa.

9. The display device of claim 1, wherein the first sensing insulating layer has a refractive index of about 1.75 to about 1.95.

10. The display device of claim 1, wherein the input sensing unit further comprises:
a second sensing insulating layer disposed on the first sensing insulating layer and configured to cover the first sensing conductive layer; and
a second sensing conductive layer disposed on the second sensing insulating layer.

11. The display device of claim 10, wherein the second sensing insulating layer comprises at least one of aluminum oxide, titanium oxide, silicon oxide, silicon nitride, silicon oxynitride, zirconium oxide, or hafnium oxide.

12. The display device of claim 10, further comprising a third sensing insulating layer disposed on the second sensing insulating layer and configured to cover the second sensing conductive layer.

13. The display device of claim 12, wherein the third sensing insulating layer comprises an organic material.

14. The display device of claim 10, wherein an electrode contact hole, which exposes at least a portion of the first sensing conductive layer and overlaps the display region, is defined in the second sensing insulating layer, and
the second sensing conductive layer is electrically connected to the first sensing conductive layer through the electrode contact hole.

15. The display device of claim 10, wherein the input sensing unit comprises:
a plurality of sensing patterns overlapping the display region and arranged in a plurality of rows and a plurality of columns;
a plurality of sensing pads overlapping the non-display region; and
a plurality of sensing wires connected to the plurality of sensing pads in a one-to-one manner such that the plurality of sensing wires electrically connects the plurality of sensing patterns and the plurality of sensing pads,
wherein the plurality of sensing patterns is included in at least one of the first sensing conductive layer or the second sensing conductive layer.

16. The display device of claim 15, wherein a pad contact hole exposing at least a portion of the plurality of sensing pads is defined in the second sensing insulating layer, and
the sensing wires are electrically connected to the plurality of sensing pads through the pad contact hole.

17. A display device comprising:
a display panel including a display region; and
an input sensing unit disposed on the display panel,
wherein the input sensing unit includes a plurality of sensing insulating layers and at least one sensing conductive layer disposed on any one of the plurality of sensing insulating layers, and
at least one of the plurality of sensing insulating layers has an atomic ratio of nitrogen (N) to silicon (Si) of about 0.69 to about 0.85.

18. A method of manufacturing a display device, the method comprising:
forming a first sensing insulating layer on a display panel;
forming a first sensing conductive layer on the first sensing insulating layer;
forming a second sensing insulating layer disposed on the first sensing insulating layer and configured to cover the first sensing conductive layer; and
forming a second sensing conductive layer disposed on the second sensing insulating layer,
wherein the first sensing insulating layer has an atomic ratio of nitrogen (N) to silicon (Si) of about 0.69 to about 0.85.

19. The method of claim 18, wherein the forming of the first sensing insulating layer is performed by a deposition process.

20. The method of claim 18, wherein the forming of the first sensing insulating layer is performed at a temperature of about 70° C. to about 100° C.
